(19) United States
(12) Patent Application Publication
(10) Pub. No.: US 2013/0242490 A1
(43) Pub. Date: Sep. 19, 2013

(54) LEATHER CASE AND HAND-HELD DEVICE HAVING TOUCH PANEL

(71) Applicant: ALLEN KU, WALNUT, CA (US)

(72) Inventor: ALLEN KU, WALNUT, CA (US)

(21) Appl. No.: 13/419,372

(22) Filed: Mar. 13, 2012

(51) Int. Cl. H05K 7/00

(52) U.S. Cl. 361/679.3; 361/679.56

(57) ABSTRACT

The instant disclosure relates to a touch panel-mounted leather case, which includes a folding cover, a base, and a touch panel. The folding cover has a first support portion and a second support portion in adjustable folding connection and cooperatively define a bending portion. The base is in adjustable folding connection to the first support portion, and the base includes a securing member. The securing member and the base cooperatively define a depression, where the touch panel is removably arranged therein. A hand-held device is also disclosed by the instant disclosure.

### BACKGROUND OF THE INVENTION

1. Field of the Invention

The instant disclosure relates to a leather case having a keyboard; in particular, to a leather case having a touch panel and a hand-held device.

2. Description of Related Art

Conventionally, portable electronic devices (such as electronic books, mobile computers, personal digital assistants (PDA), mobile phones, etc.) for internet surfing and telecommunication are equipped with basic office softwares or editing tools. Therefore, users can manage their business or private affairs while travelling either on business or private trips by using such tools. Typically, the protection covers designed for aforementioned portable electronic devices mainly provide easy portability, anti-vibration, and anti-collision functions. For in use, the protection covers having an electronic device is flipped open and arranged stably on the table. To satisfy the need of portability, the protection covers are generally designed to have a thin structure. However, if a keyboard is to be used along with the electronic device, the keyboard must be relatively small and is usually equipped with discrete keys with its own key caps. Therefore, when inputting commands, the user is forced to apply a strong stroke to mash the keys. After a long period of time, the users' hands may get very tired. In addition, in order for the protection covers to receive the keyboards, the protection covers usually become more bulky while compromising its portability. These issues discourage the consumers from purchasing the protection covers.

To address the above issues, the inventor strives via industrial experience and academic research to present the instant disclosure, which can effectively improve the limitations described above.

### SUMMARY OF THE INVENTION

The object of the instant disclosure is to provide a leather case having a touch panel, which includes a folding cover, a base, and a touch panel. The folding cover has a first support portion and a second support portion in adjustable folding connection that defines a bending portion. The second support portion has a first holding member. The base is in adjustable folding connection with the first support portion and has a securing member. A depression to accommodate the keyboard is defined by the securing member and the base. The keyboard may be removably disposed in the depression.

An embodiment of the instant disclosure further provides a hand-held device which includes a folding cover, a base, a touch panel, and a flat electronic device. The folding cover has a first support portion and a second support portion in adjustable folding connection that defines a bending portion. The second support portion has a first holding member. The base is in adjustable folding connection with the first support portion and has a securing member. A depression to accommodate the keyboard is defined by the securing member and the base. The keyboard may be removably disposed in the depression. The flat electronic device is secured by the first holding member which is connected electronically to the touch panel.

For the leather case and the hand-held device provided in the instant disclosure, the flat electronic device can be selectively received therein. Therefore, by adjusting the angle of the leather case, the flat electronic device can be arranged at different angles. Thus, the flat electronic device can be used more conveniently with the touch panel.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows an exploded view of a leather case having a touch panel according to the instant disclosure;

FIG. 2 shows a cross-sectional view of the touch panel according to the instant disclosure;

FIG. 3 shows an exploded view of another leather case having a touch panel according to the instant disclosure;

FIG. 4 shows a perspective view of a hand-held device under operation according to the instant disclosure;

FIG. 5 shows another perspective view of the hand-held device under operation according to the instant disclosure;

FIG. 6 shows yet another perspective view of the hand-held device under operation according to the instant disclosure.

### DETAILED DESCRIPTION OF THE PREFERRED EMBODIMENTS

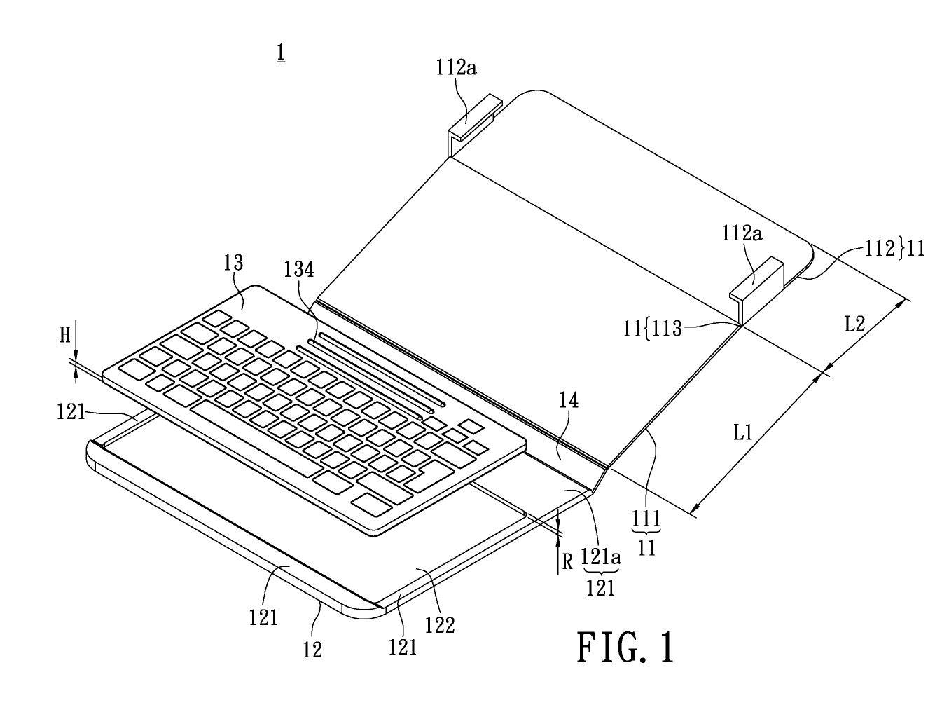

Please refer to FIGS. 1-6. The instant disclosure provides a touch panel-mounted leather case 1, which includes a folding cover 11, a base 12, and a touch panel 13. The folding cover 11 has a first support portion 111 and a second support portion 112 in adjustable folding connection that defines a bending portion 113. Similarly, the base 12 is also in adjustable folding connection with the first support portion 111. Thus, based on the requirements, the user can adjust the angle of the bending portion 113 and the angle between the base 12 and the first support portion 111. Therefore, the leather case 1 can be set up having different angles with much flexibility.

The base 12 has a securing member 121, where a depression 122 is cooperatively defined by the securing member 121 and the base 12. The touch panel 13 can be removably disposed in the depression 122. Additionally, the second support portion 112 has at least one first holding member 112a for securing a flat electronic device (not shown). Therefore, the leather case 1 of the instant disclosure can selectively receive the flat electronic device. Furthermore, the flat electronic device and the touch panel 13 can co-exist in the leather case 1. Therefore, other than providing easy portability, the leather case 1 also enables the flat electronic device to be used alongside with the touch panel 13 as a complete unit.

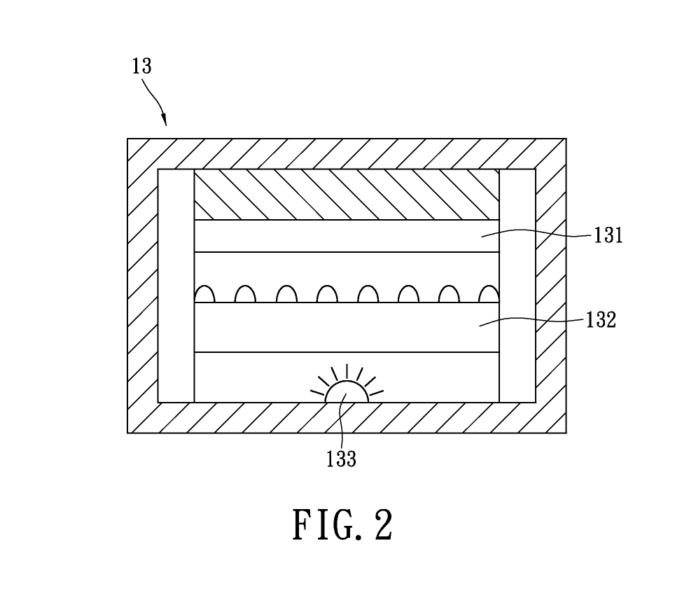

In the following illustrations, a detail description of the embodiment of the instant disclosure will be provided. With reference to FIGS. 1-2, where FIG. 1 shows an exploded view of the leather case having the touch panel according to the instant disclosure. And FIG. 2 shows a cross-sectional view of the touch panel according to the instant disclosure. As shown in FIG. 1, the leather case 1 of the instant disclosure includes the folding cover 11, the base 12, and the touch panel 13. The securing member 121 of the base 12 is formed of a ring-like structure 121a having a predetermined thickness R. The thickness R and the base 12 together define the aforementioned depression 122. Since the touch panel 13 is defined having a thickness H, the touch panel 13 can be precisely secured in the depression 122 defined by the ring-like structure 121a having the thickness R and the base 12. Also, the touch panel 13 has the same shape as the depression 122. Therefore, the touch panel 13 can be received entirely by the depression 122. Furthermore, because the touch panel 13 has a low profile, the thickness H is very small. Thus, the thickness R of the ring-like structure 121a may be kept small accordingly for space saving. In other words, the leather case 1 of the instant disclosure is smaller in size and has less weight in promoting portability, besides being aesthetically appealing. Material-wise, the leather case 1 can be made of real or synthetic leather such as polyurethane. Whereas the touch panel 13 may be a resistive or capacitive type touch panel.

As shown in FIG. 2, the touch panel 13 of the instant embodiment is a resistive touch panel, which includes a thin film 131, a glass substrate 132, and a backlight module 133. For the orientation shown in the figure, the backlight module 133 is arranged under the thin film 131 and the glass substrate 132. At least one isolating layer is formed around the periphery of the thin film 131 and the glass substrate 132. When light is projected to the thin film 131 and the glass substrate 132 from the backlight module 133, the user may use his/her fingertip or a stylus to touch the surface of the touch panel. The touch generates an electrical signal, where different technologies may be used to determine the location of the touch. The location is then sent to a controller for processing to execute the command. Since the touch panel 13 can be easily operated by the user with a light stroke, the user will feel less fatigue with their hands.

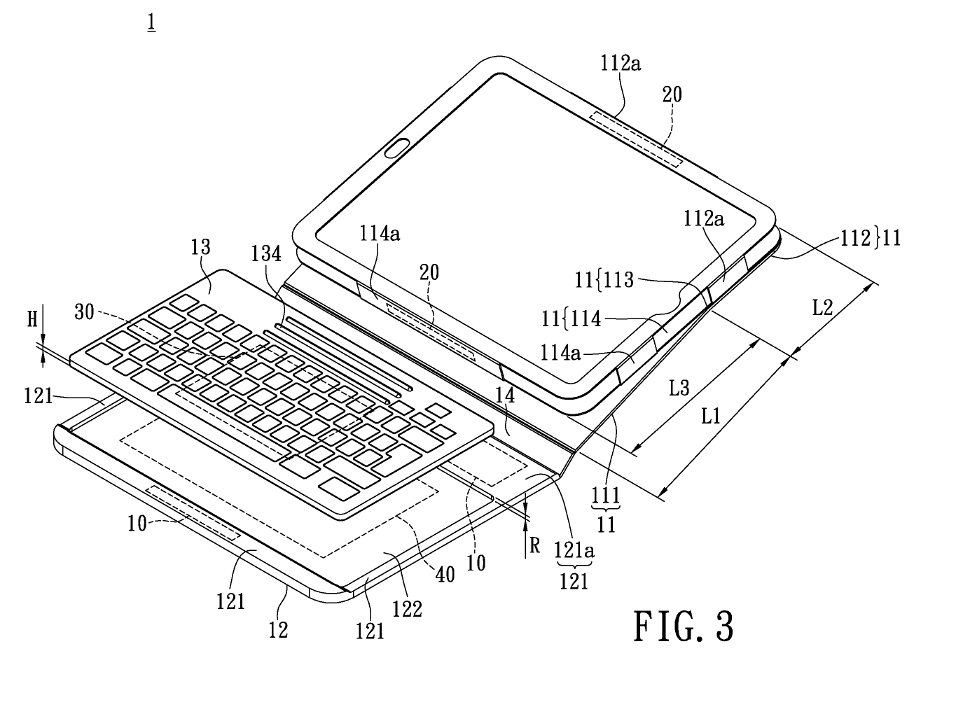

Please refer to FIG. 3 which shows an exploded view of a leather case having a touch panel for another embodiment of the instant disclosure. As shown in FIG. 3, the instant disclosure provides a variant of the touch panel-mounted leather case 1, which includes the folding cover 11, the base 12, and the touch panel 13. The main difference between the instant embodiment and the preceding embodiment is that the second support portion 112 of the folding cover 11 can be extended to form a support frame 114. The support frame 114 can further have a second holding member 114a. Together, the first and second holding members 112a and 114a cooperatively define a receiving space (not labeled) to secure and protect the flat electronic device (not shown) therein. Moreover, to secure the touch panel 13 more stably in the depression 122, at least one third magnetic member 30 can be arranged on the touch panel 13. Correspondingly, at least one fourth magnetic member 40 can be arranged on the base 12. Therefore, the third and fourth magnetic members 30 and 40 are arranged to complement each other, such that the touch panel 13 is more firmly secured in the depression 122 by the magnetic attraction between the third and fourth magnetic members 30 and 40. The shape, quantity, material, and arrangement of the third and fourth magnetic members 30 and 40 are not restricted. The third and fourth magnetic members 30 and 40 can be a pair of complementing magnets or magnetic member units with plate-, strip-, or circular-liked shapes. For the instant embodiment, the third magnetic member 30 can be a plate-shaped magnet arranged internally of the touch panel 13, while the fourth magnetic member 40 can be an iron strip. In addition, the securing member 121 of the base 12 and the first holding member 112a of the second support portion 112 can further include a first magnetic member 10 and a second magnetic member 20, respectively. Therefore, the folding cover 11 and the base 12 can be held tightly together when the leather case 1 is closed through the magnetic attraction between the first and second magnetic members 10 and 20.

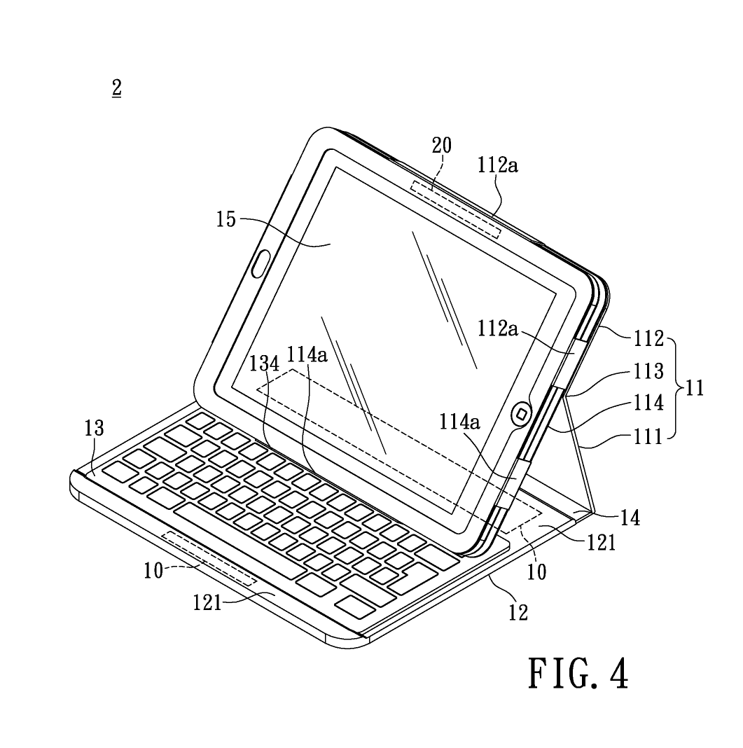

Note that at least one display-rest 134 can be formed on the touch panel 13, where the quantity, shape, and arrangement of the display-rest 134 are not restricted. For the instant embodiment, three display-rests 134 each being an elongated slot is arrayed on the touch panel 13 parallel to the adjacent side portion of the support frame 114. In use, the support frame 114 can selectively abuts against one of the display-rests 134 to adjust the viewing angle of the flat electronic device (shown in FIG. 4).

Please refer to FIGS. 4-6, where the instant disclosure further provides a hand-held device 2, which includes the folding cover 11, the base 12, the touch panel 13, and a flat electronic device 15. Since the technical features of the folding cover 11, the base 12, and the touch panel 13 are identical to the preceding embodiment, no further illustrations shall be provided herein. The flat electronic device 15 can be securely retained within the receiving space (not labeled) cooperatively defined by the first and second holding members 112a and 114a. Therefore, the flat electronic device 15 can be kept from shaking undesirably and dropping accidentally from the folding cover 11. In addition, the flat electronic device 15 can be connected electrically to the touch panel 13. Therefore, the user can conveniently operate the flat electronic device 15 through the touch panel 13. Moreover, please refer to FIG. 3 in conjunction with FIGS. 4˜6, the width L1 of the first support portion 111 is greater than the width L2 of the second support portion 112, while the width L3 of the support frame 114 is smaller than or equal to the width L1 of the first support portion 111. Therefore, when the flat electronic device 15 is secured on the second support portion 112, the first support portion 111 is capable of supporting the entire flat electronic device 15. Furthermore, by adjusting the angle of the bending portion 113, the support frame 114 can be moved toward or away from the first support portion 111. Thus, the flat electronic device 15 can be arranged at different viewing angles accordingly.

Note that when the hand-held device 2 of the instant disclosure is foldingly closed, the flat electronic device 15 can automatically switch to the sleep mode. This change of power mode is explained in further details hereinbelow. A detector can be arranged internally within the flat electronic device 15. The detector has internal magnets with alternating polarities (+−+−), which is complemented by the opposite alternating polarity (−+−+) of the first magnetic member 10 of the securing member 121 of the base 12. Therefore, when the folding cover 11 and the base 12 approach each other, the presence of the magnetic field is detected by the detector that enables the flat electronic device 15 to enter the sleep mode for saving energy consumption. Additionally, the folding cover 11, the spine 14, and the base 12 of the hand-held device 2 of the instant disclosure are foldingly connected to each other. Furthermore, the width of the spine 14 is greater than the thickness of the flat electronic device 15. Therefore, when the folding cover 11 and the base 12 approach each other to close the hand-held device 2, the flat electronic device 15 can be received and protected effectively.

FIG. 4 shows the hand-held device 2 while in use. The hand-held device 2 is capable of integrating the touch panel 13 and the flat electronic device 15 together. When using the hand-held device 2, if the user intends to adjust the viewing angle of the flat electronic device 15, the user can simply adjust the position of the support frame 114 relative to the first support portion 111, since the flat electronic device 15 is retained by the support frame 114 of the second support portion 112. Then, the support frame 114 can be disposed on any of the display-rests 134 of the touch panel 13. By using different display-rests 134 for the support frame 114, the flat electronic device 15 can be inclined at different viewing angles. Thus, the user can operate the flat electronic device 15 along side with the touch panel 13 with more ease.

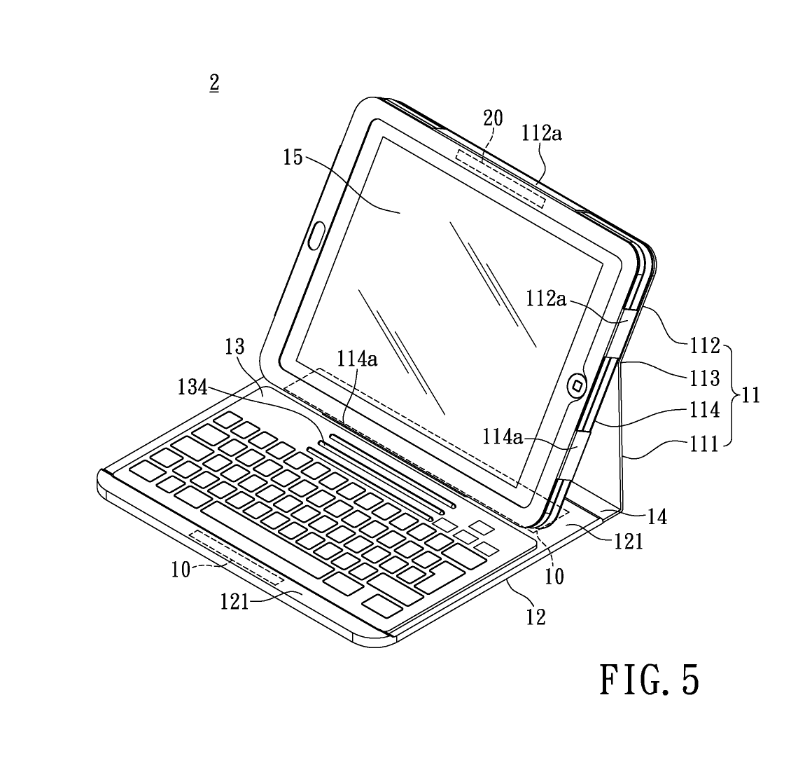

FIG. 5 shows another perspective view of the hand-held device 2 while in use. As shown in FIG. 5, when the user intends to use the flat electronic device 15, the bending portion formed between the first and second support portions 111 and 112 can be adjusted to an angle greater than 90 degrees. Furthermore, by the magnetic attraction between the first magnetic member 10 arranged on the securing member 121 of the base 12 and the second magnetic member 20 arranged on the second holding member 114a of the support frame 114 (shown in FIG. 3), the support frame 114 can be firmly arranged on the securing member 121 proximate to the spine 14. Thus, the flat electronic device 15 can be used along with the touch panel 13 in a secured manner.

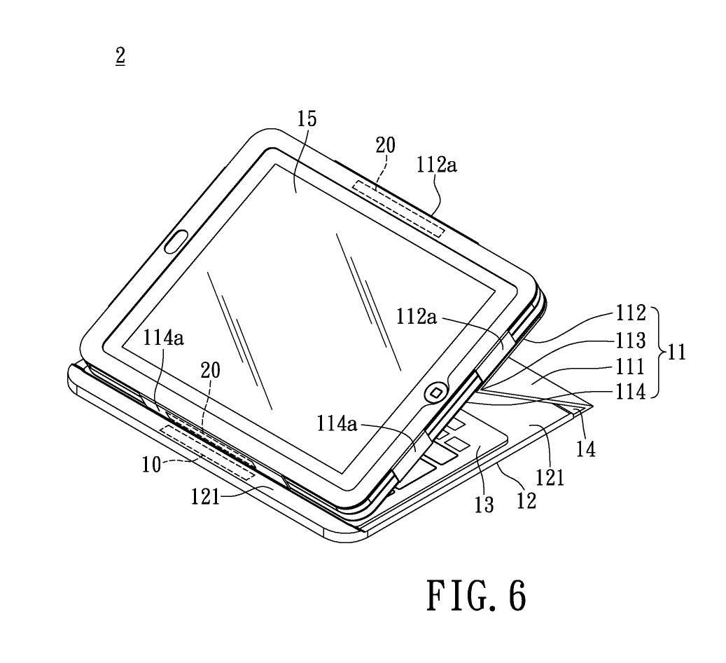

FIG. 6 shows yet another perspective view of the hand-held device 2 while in use. When the user decides to operate the flat electronic device 15 directly without the touch panel 13, the user can again manipulate the support frame 114 to adjust the viewing angle of the flat electronic device 15. More specifically, the bending can be adjusted to an angle less than 90 degrees. Similarly, by the magnetic attraction between the first magnetic member 10 arranged on the securing member 121 of the base 12 and the second magnetic member 20 arranged on the second holding member 114a of the support frame 114, the support frame 114 can be firmly arranged on the securing member 121 away from the spine 14. Thereby, the flat electronic device 15 is sloped at the greatest angle of inclination to suit the user.

For the gains, the touch panel-mounted leather case and the hand-held device of the instant disclosure have the following advantages:

1. The viewing angle of the flat electronic device can be adjusted effectively and the flat electronic device can be stored and protected securely.

2. The flat electronic device and the touch panel can be operated and carried by the user as a complete unit.

3. The base and the folding cover can be downsized to enhance portability.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A touch panel-mounted leather case, comprising:
a folding cover having a first support portion and a second support portion in adjustable folding connection and cooperatively define a bending portion, wherein the second support portion includes at least one first holding member;
a base in adjustable folding connection to the first support portion, wherein the base includes a securing member, where the base and the securing member cooperatively define a depression; and
a touch panel removably arranged in the depression.

2. The touch panel-mounted leather case according to claim 1, wherein the securing member is a ring-like structure having a predetermined thickness in defining the depth of the depression.

3. The touch panel mounted leather case according to claim 1, wherein the touch panel is a resistive or a capacitive touch panel.

4. The touch panel-mounted leather case according to claim 3, wherein the securing member has a first magnetic member and the second holding member has a second magnetic member for holding the folding cover and base together when the leather case is closed.

5. The touch panel-mounted leather case according to claim 1, wherein the width of the first support portion is greater than the width of the second support portion.

6. The touch panel-mounted leather case according to claim 1, wherein the second support portion extends in forming a support frame having a second holding member.

7. The touch panel-mounted leather case according to claim 6, wherein the width of the support frame is smaller than or equal to the width of the first support portion.

8. The touch panel-mounted leather case according to claim 1, further comprising a spine which acts as a pivot foldably connected between the first support portion and the base for closing or opening the leather case.

9. The touch panel-mounted leather case according to claim 1, wherein the touch panel has a third magnetic member and the base has a fourth magnetic member.

10. The touch panel-mounted leather case according to claim 1, wherein the touch panel has at least one display-rest formed thereon.

11. A hand-held device, comprising:
a folding cover having a first support portion and a second support portion in adjustable folding connection and cooperatively defining a bending portion, wherein the second support portion includes at least one first holding member;
a base in adjustable folding connection to the first support portion and having a securing member, wherein the securing member and the base cooperatively define a depression;
a touch panel removably arranged in the depression; and
a flat electronic device secured by the first holding member and is connected electrically to the touch panel.

12. The hand-held device according to claim 11, wherein the securing member is a ring-like structure having a predetermined thickness in defining the depth of the depression.

13. The hand-held device according to claim 11, wherein the touch panel is a resistive or a capacitive touch panel

14. The hand-held device according to claim 13, wherein the securing member has a first magnetic member and the second holding member has a second magnetic member for holding the folding cover and base together when the leather case is closed.

15. The hand-held device according to claim 11, wherein the width of the first support portion is greater than the width of the second support portion.

16. The hand-held device according to claim 11, wherein the second support portion extends in forming a support frame having a second holding member, wherein the flat electronic device is secured by the first and second holding members.

17. The hand-held device according to claim 16, wherein the width of the support frame is smaller than or equal to the width of the first support portion.

18. The hand-held device according to claim 11, further comprising a spine foldably connected between the first support portion and the base as a pivot for closing or opening the leather case, wherein the width of the spine is greater than the thickness of the flat electronic device.

19. The hand-held device according to claim 11, wherein the touch panel has a third magnetic member and the base has a fourth magnetic member.

20. The hand-held device according to claim 11, wherein the touch panel has at least one display-rest formed thereon.
